(19) United States
(12) Patent Application Publication
(10) Pub. No.: US 2013/0000847 A1
(43) Pub. Date: Jan. 3, 2013

(54) PLASMA PROCESSING APPARATUS

(75) Inventors: Tsutomu TETSUKA, Kasumigaura (JP); Ryoji NISHIO, Kudamatsu (JP)

(73) Assignee: Hitachi High-Technologies Corporation

(21) Appl. No.: 13/209,523

(22) Filed: Aug. 15, 2011

(30) Foreign Application Priority Data
Jun. 28, 2011 (JP) 2011-143406

(51) Int. Cl. H01L 21/3065; C23C 16/505

(52) U.S. Cl. 156/345.33; 118/723 I

(57) ABSTRACT

There is provided a plasma processing apparatus enabling uniform plasma processing over the entire surface of a sample, without causing abnormal discharge even when the electromagnetic field strength is strong as in the case of the inductive coupling method. The plasma processing apparatus includes a process chamber, a first dielectric vacuum window, an inductive coil, a radio-frequency power supply, a gas supply unit, and a sample holder. The gas supply unit includes a second dielectric gas guide plate and a third dielectric island member. The second dielectric gas guide plate is located near below the vacuum window, and has a gas inlet port in the center. The third dielectric island member is provided in a gap between the vacuum window and the gas guide plate. The dielectric constant of the third dielectric is higher than the dielectric constant of the first and second dielectrics.

### CLAIM OF PRIORITY

The present application claims of priority from Japanese patent application JP 2011-143406 filed on Jun. 28, 2011, the content of which is hereby incorporated by reference into this application.

### FIELD OF THE INVENTION

The present invention relates in particular to a plasma processing apparatus using inductive plasma coupling (IPC) techniques.

### BACKGROUND OF THE INVENTION

Plasma processing apparatus is widely used for deposition and etching process in manufacturing semiconductor devices. In each process, a uniform process is performed by generating plasma from various gases according to the process content.

The plasma processing apparatus described in Japanese Patent Application Laid-Open Publication No. 2005-101656 has been used as a gas supply method in a plasma processing apparatus of the microwave method. As described in Japanese Patent Application Laid-Open Publication No. 2005-101656, microwaves pass through a process chamber to generate plasma. A quartz window is provided above the process chamber. A quartz plate is provided close to the quartz window. A gas supply port is formed in the center of the quartz plate. Gas is introduced between the quartz window and the quartz plate near the side wall of the process chamber. Then, the gas is introduced into the process chamber from the gas supply port in the center of the quartz plate. The introduced gas is dissociated and ionized in the plasma. A part of reactive radicals is used in the process of a sample placed on a sample holder located below the process chamber. The process chamber has a gas exhaust port. The supplied gas passes through the plasma to flow to the exhaust port. Then, the supplied gas is exhausted from the exhaust port.

The plasma processing apparatus described in Japanese Patent Application Laid-Open Publication No. 2005-196994 has been used as a gas supply method in a plasma processing apparatus of the microwave method. As described in Japanese Patent Application Laid-Open Publication No. 2005-196994, the plasma processing apparatus includes an antenna for emitting microwaves into the process chamber, dielectric cover plates arranged at intervals in the antenna, and a dielectric shower plate having a large number of gas holes located just below the cover plates. A process gas is supplied to the gas inlet hole of the shower plate through a gas flow space between the upper surface of the shower plate and the lower surface of the cover plate partially abutting the upper surface of the shower plate. In this state, microwaves are emitted from the antenna to generate plasma in the space in the lower surface of the shower plate. In this case, the dielectric constant of the cover plate is lower than the dielectric constant of the shower plate that contacts the plasma. In this way, the electric field concentration in the corner of the gas flow space is suppressed to prevent abnormal discharge.

The plasma processing apparatus described in Japanese Unexamined Patent Application Publication (Translation of PCT Application) No. 2002-511905 has been used as a gas supply method in a plasma processing apparatus of the inductive plasma coupling method. As described in Japanese Unexamined Patent Application Publication (Translation of PCT Application) No. 2002-511905, in the case of the inductive plasma coupling method, a planar inductive coil is placed above of the process chamber to serve as a radio-frequency antenna for plasma generation. Further, a vacuum window of dielectric material is located just below the coil. The supply of the process gas is performed by supplying gas from a hole formed in the side wall of the process chamber. At this time, the gas is supplied to a sample from the side surface by an injection tube, to control the gas supply distribution.

The plasma processing apparatus described in Japanese Unexamined Patent Application Publication (Translation of PCT Application) No. 2002-534797 has been used as another gas supply method in the plasma processing apparatus of the inductive plasma coupling method. As described in Japanese Unexamined Patent Application Publication (Translation of PCT Application) No. 2002-534797, a removable gas injection unit is provided in the center of the vacuum window of a dielectric member located above the process chamber. The process gas is supplied from the center of the vacuum window.

### SUMMARY OF THE INVENTION

In recent years, the size of samples to be processed such as wafers and display substrates has been gradually increased. Under these circumstances, in the plasma processing apparatus, it is important to uniformly process a sample by controlling the supply of process gas to the surface of the sample. This is because the space distribution of the plasma distribution is determined by the dissociation and ionization of the supplied mother gas. The mother gas is excited in the plasma to produce reactive radicals that directly affect the distribution of the process characteristics. In addition, the exhaust of the reactive products that hinder the process is affected by the distribution of the mother gas flow, along with the transmission of the reactive radicals involved in the process.

Further, the larger the sample the larger the plasma diameter has to be, requiring a high input power for plasma generation. Thus, for the gas supply mechanism of the plasma processing apparatus, it is important to be able to control the gas supply distribution with respect to the large-diameter plasma from which a high power electromagnetic field is emitted.

In the case of the microwave plasma processing apparatus described in Japanese Patent Application Laid-Open Publication No. 2005-101656, it is possible to supply gas to the center of the process chamber through the process gas between the quartz vacuum window and the quartz plate. Thus, it is possible to control the gas supply distribution. However, this method may not be applicable if the voltage between terminals of the inductive coil is high as in the case of the inductive coupling method. The reason will be described below.

The voltage at the time when an abnormal discharge occurs between the dielectric vacuum window and the dielectric plate, is estimated from the breakdown voltage between parallel planar plates (Paschen's Curve, which is well-known). In general, the gas pressure in the gas flow path is a pressure of a range from about 100 Pa to about 500 Pa, and the distance between the dielectric plates is 1 mm or less. Assuming that the gas pressure P is 500 Pa and the dielectric plate distance d is 1 mm, the breakdown voltage parameter Pd (Torr-cm) is defined by Pd=0.37. In the case of argon gas, the breakdown voltage is estimated to be about 200 V. The estimated breakdown voltage, which varies according to the gas type and gas pressure, can easily exceed the breakdown voltage in the vicinity of the inductive coil of the inductive coupling method. In general, in a plasma processing apparatus for a wafer with a diameter of 300 mm, the voltage between terminals of the inductive coil is several kV when a radio-frequency of 13.56 MHz is used. In other words, abnormal discharge is unavoidable if nothing is done in the case of the inductive coupling method. Thus, it is necessary to develop a technology to reduce the electric filed strength of the gas flow path to a level below the breakdown voltage.

The method for reducing the electric filed concentration in the corner by forming the cover plate from a material with a dielectric constant lower than that of the shower plate for supplying the gas, is not effective in suppressing abnormal discharge in the gas flow path when the entire electric field is strong as in the case of the inductive coupling method.

In the case of supplying the process gas from the side wall of the process chamber, which is used in the inductive coupling method, if the diameter of the sample to be processed is large, it is difficult to control the supplying of the process gas to the entire surface of the sample. Further, in the case of the method for supplying the gas from the side wall of the process chamber, it is difficult to quickly flow the reactive products produced from the sample surface during the process, to the exhaust port located in the outer periphery.

Further, in the case of the method for providing the gas inlet unit in the center of the coil in which the induced electromagnetic field by the inductive coil is relatively weak, the location of the gas inlet unit is limited to a small area in the center of the coil in which the electromagnetic filed excited by the inductive coil is relatively weak. For this reason, the gas injection unit is preferably formed by a dielectric material that is not likely to have an influence on the electromagnetic field. At the same time, it is necessary to reduce the size of the gas injection unit. Because the gas supply location is limited to the central portion of the coil, the controllability of the distribution of gas supply to the sample surface is not necessarily good. In addition, the shape of the conductive coil and faraday shield is limited so that the gas inlet unit can be provided in the center of the inductive coil.

Further, as described above, when the gas flow path is provided in the vicinity of the inductive coil of the inductive coupling method, abnormal discharge occurs unless the depth of the gas flow path is made as small as possible. Thus, in order to directly provide the gas flow path in the vacuum window of dielectric material (for example Al₂O₃), it is necessary to form a groove of 1 mm or less for the gas flow path, in the Al₂O₃ vacuum window. However, it is not easy to form a groove of 1 mm or less for the gas flow path in the Al₂O₃ vacuum window with a high accuracy.

In view of the above problems, it is desirable to provide a plasma processing apparatus enabling uniform plasma processing over the entire surface of a sample, without causing abnormal discharge when the electromagnetic field strength is strong as in the case of the inductive coupling method.

To achieve the above object, one embodiment of the present invention provides a plasma processing apparatus that includes: a process chamber for plasma processing an object to be processed; a first dielectric vacuum window for vacuum sealing the top of the process chamber; an inductive coil located above the vacuum window; a radio-frequency power supply for supplying radio-frequency power to the inductive coil; a gas supply unit for supplying gas into the process chamber; and a sample holder on which the object to be processed is placed in the process chamber. The gas supply unit includes: a second dielectric gas guide plate located near below the vacuum window, and has a gas inlet port in the center thereof; and a third dielectric island member provided between the vacuum window and the gas guide plate. The dielectric constant of the third dielectric island member is higher than the dielectric constant of the first and second dielectrics. The gas transmitted to the gas flow path formed by the gap and the island member, is supplied into the process chamber through the gas inlet port located in the center of the gas guide plate.

Further, in the above configuration, the third dielectric island member can be replaced by a conductor.

According to the embodiments of the present invention, the third dielectric with a dielectric constant higher than the dielectric constant of the first dielectric material forming the vacuum window, and of the second dielectric material forming the gas inlet unit, is provided between the second and third dielectrics. With this configuration, it is possible to provide a plasma processing apparatus enabling uniform plasma processing over the entire surface of a sample, without causing abnormal discharge when the electromagnetic field strength is strong as in the case of the inductive coupling method. Further, the same effect can be obtained by using a conductor in place of the third dielectric island member.

### BRIEF DESCRIPTION OF THE DRAWINGS

FIG. 1 is a cross-sectional view schematically showing the configuration of a plasma processing apparatus according to a first embodiment of the present invention;

FIG. 2 is a detailed view of a gas guide plate in the plasma processing apparatus shown in FIG. 1, in which the upper diagram is a top view and the lower diagram is an X-X′ cross-sectional view;

FIG. 3 is a detailed view of a gas guide plate in the plasma processing apparatus according to a second embodiment of the present invention, in which the upper diagram is a top view, the middle diagram is an A-A′ cross-sectional view, and the lower diagram is a B-B′ cross-sectional view;

FIG. 4 is a detailed cross-sectional view of a gas guide plate in the plasma processing apparatus according to a third embodiment of the present invention;

FIGS. 5A and 5B are views showing the first embodiment of the present invention, in which FIG. 5A is a cross-sectional view schematically showing the configuration in the vicinity of the gas guide plate in the plasma processing apparatus shown in FIG. 1, while FIG. 5B is a graph showing the relationship, in the gas flow path (height H, width W) shown in FIG. 5A, between the standardized electric field strength (calculation result) and W/H; and

FIG. 6 is a view showing the calculation result of the electric field vector in the gas flow path according to the first embodiment of the present invention.

### DETAILED DESCRIPTION OF THE PREFERRED EMBODIMENTS

Hereinafter preferred embodiments of the present invention will be described with reference to the accompanying drawings.

### First Embodiment

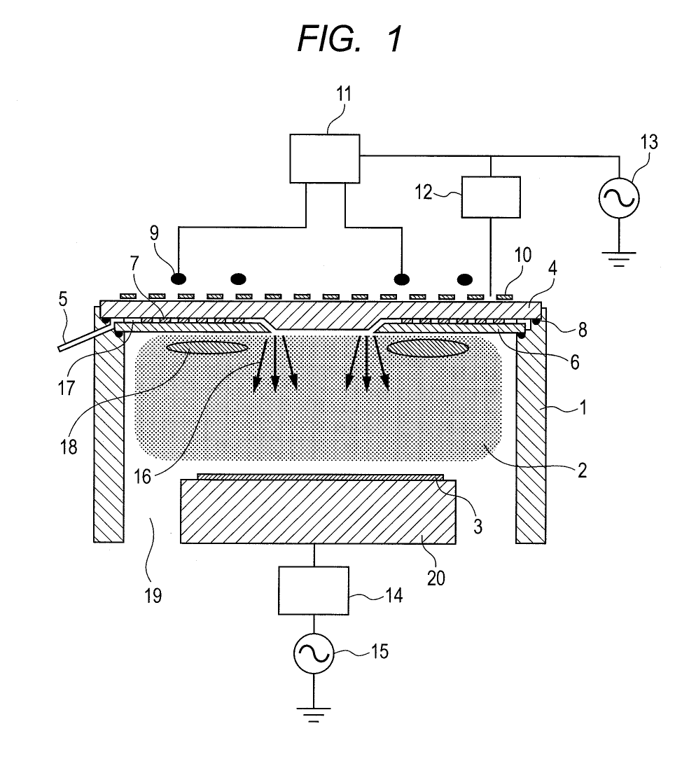

A first embodiment of the present invention will be described with reference to FIG. 1. FIG. 1 is a schematic diagram of a plasma processing apparatus according to the first embodiment. A sample (an object to be processed) 3, such as a semiconductor device wafer or a liquid crystal display substrate, is placed on a sample holding electrode (sample holder) 20. The sample holder has an electrostatic adsorption function and is provided in a process chamber 1. A radio-frequency of several tens of MHz or less is applied from a radio-frequency power supply 15 to the sample 3 through a matching box 14, to control the ion energy from a plasma 2 incident on the sample 3. In this embodiment, a semiconductor device wafer with a diameter of 300 mm is used as the sample 3, and a power supply with a frequency of 800 kHz is used as the radio-frequency power supply 15. The side wall of the process chamber 1 is formed by thermally spraying ceramic onto aluminum base metal. A dielectric vacuum window 4 of quartz is vacuum sealed by an O ring 8 above the process chamber 1. Below the process chamber 1, an exhaust port 19 is provided between the electrode (sample holder) 20 on which the sample 3 is placed, and the side wall of the process chamber 1. So the pressure within the process chamber 1 is controlled to a set pressure in the range from 0.1 Pa to several tens of Pa.

The gas supplied to the plasma process is introduced from a gas supply tube 5 provided in the side wall of the process chamber 1. Then, a process gas 16 is introduced from above the sample 3 through a gas flow path 17 between the dielectric vacuum window 4 and the gas guide plate 6 of quartz. The process gas 16 is introduced from a slit in the circumferential direction. The slit is formed between a circular and trapezoidal projection provided in the center of the dielectric vacuum window 4, and a circular opening provided in the center of the gas guide plate 6. It is to be noted that the planar shape of the trapezoidal projection and the opening is not necessary a circular shape, but the circular shape is easy to manufacture. When the gap (H) of the slit formed between the trapezoidal projection and the opening is sufficiently small, it is possible to reduce the potential difference in the gap with respect to the breakdown voltage estimated from Paschen's Curve (H×electric field strength). Thus, the occurrence of abnormal discharge can be prevented. Instead of supplying the process gas 16 from the slit in the circumferential direction, it is also possible to inject the process gas 16 in the direction of the sample 3 from plural holes like a shower formed on the gas guide plate 6. The location and angle at which the process gas 16 is injected can be optimized with respect to the supply of the reactive radicals to the sample 3 as well as the exhaust of the reactive products.

The distance between the dielectric vacuum window 4 and the gas guide plate 6 is 1 mm or less. A dielectric 7 of alumina ceramic is inserted into the gas flow path 17 in an island-like manner. The purpose of inserting the dielectric 7 is to reduce the electric field in the gas flow path 17. Thus, the dielectric 7 may be inserted only in the vicinity of the radio-frequency antenna (inductive coil) 9, or may be inserted between a faraday shield 10 and a high density plasma region.

In the electromagnetic field for generating the plasma 2, the output of the radio-frequency power supply 13 at a frequency of 13.56 MHz is applied to the coiled radio-frequency antenna 9 through a matching box 11. Then, the plasma 2 is discharged into the process chamber 1. When the output of the radio-frequency power supply 13 is several kW, the radio-frequency antenna 9 has an inductance of several μH with a radio-frequency current of several tens of A. At this time, the inter-terminal voltage is several kV. In order to prevent the high voltage of the radio-frequency antenna 9 from being directly applied to the plasma 2, the faraday shield 10, which is a metal plate on which a slit is formed radially, is provided between the radio-frequency antenna 9 and the plasma 2. The potential of the faraday shield 10 can be grounded or apply radio-frequency by a matching box 12 connected to the radio-frequency power supply 13. The electromagnetic field is generated by the coiled radio-frequency antenna 9 and generates a strong induced current 18 on the surface of the plasma in the vicinity of the radio-frequency antenna 9.

As a result, a high electric field is generated between the radio-frequency antenna 9 and the plasma 2. In particular the electric field is high in the dielectric vacuum window 4 and the gas flow path 17 near the radio-frequency antenna 9. So there is a risk of abnormal discharge in the gas flow path 17. Further, in general, the gas pressure within the gas flow path 17 is kept at a high pressure of a range from about 100 Pa to about 500 Pa. The reactive gas is injected into the process chamber 1 of a low pressure (several tens of Pa or less) from the gas flow path 17. Because of the high pressure in the gas flow path 17, the abnormal discharge is relatively likely to occur. At this time, the resistance of the high density plasma just below the radio-frequency antenna 9 is reduced to the level of the conductor. Thus, a strong electric field is generated in the vertical direction between the parallel plate electrodes in which the faraday shield 10 and the upper surface of the plasma 2 face each other.

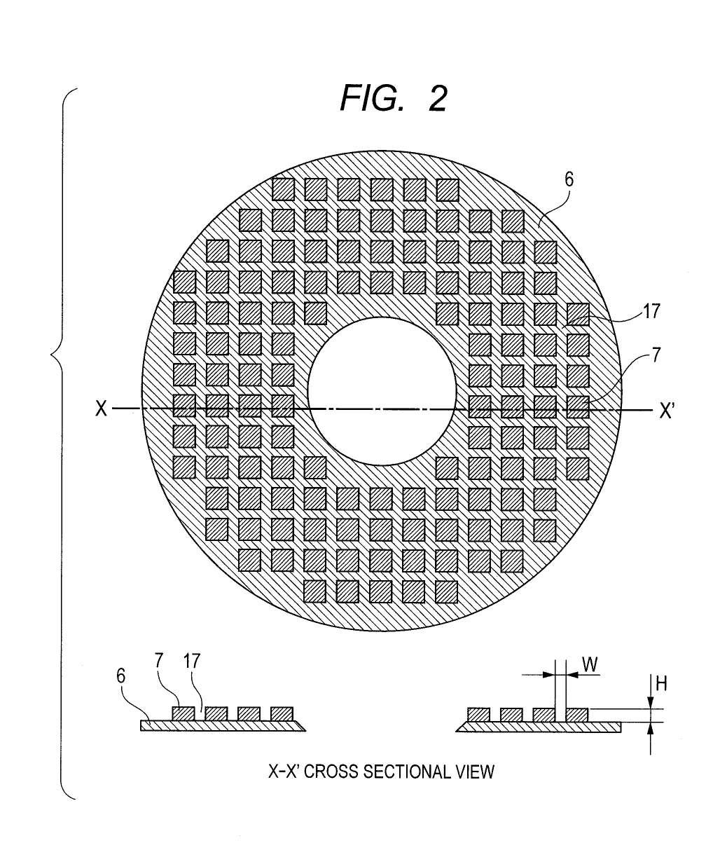

The details of the dielectric 7 will be described with reference to FIG. 2. FIG. 2 is a detailed view of the gas guide plate in which the dielectrics 7 are provided. The upper diagram is a top view, and the lower diagram is a cross-sectional view along line X-X′. The gas guide plate 6 uses quartz for plasma generation. Quartz has a small loss in the transmission of the electromagnetic waves, and has a high resistance against the reactive gas and plasma. The outer diameter of the gas guide plate 6 is set to 400 mm and the thickness thereof is set to 10 mm. Examples of the material of the gas guide plate 6, in addition to quartz, are ceramics such as alumina and yttria, as well as compounds such as silicon nitride (SiN), aluminum nitride (AlN), and zirconia. The dielectric 7 uses alumina ceramic (dielectric constant: about 10) with a small loss in the transmission of the electromagnetic waves and has a good resistance against the reactive gas, similarly to the gas guide plate 6. However, alumina ceramic has a dielectric constant relatively higher than the dielectric constant of quartz (dielectric constant: about 3.5). The shape of the dielectric 7 is square with the length of each side being several tens of mm and a thickness H of about 0.5 mm. The dielectrics 7 of this size are arranged at a distance W (about 1 mm) on the surface of the gas guide plate 6, and bonded with a commercially available ceramic adhesive. The process gas supplied from the outer periphery of the gas guide plate 6 flows to the center of the gas guide plate 6 through the gas flow paths 17 between the individual dielectrics 7. In this embodiment, the dielectrics 7 are bonded with the adhesive. However, it is also possible that the dielectric material is thermally sprayed or deposited onto the gas guide plate 6, or simply held between the gas guide plate 6 and the dielectric vacuum window 4. Further, in this embodiment, the dielectrics 7 are attached to the gas guide plate 6. However, it is also possible that the dielectrics 7 is bonded or thermally sprayed onto the dielectric vacuum window facing the gas guide plate 6.

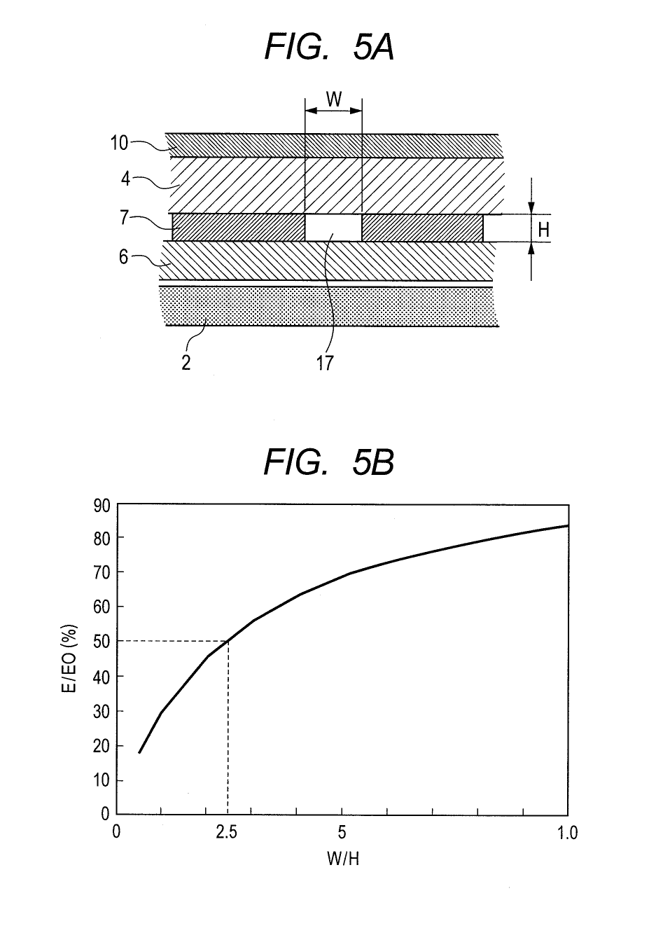

The effect of reducing the electric field by the dielectrics 7 will be described with reference to FIGS. 5A and 5B. This calculation assumes that the plasma 2 is the ground potential with the voltage applied to the faraday shield 10. FIG. 5A is a cross-sectional view schematically showing the vicinity of the gas flow path. The dielectric vacuum window 4 is made from 20 mm thick quartz, and the gas guide plate 6 is made from 10 mm thick quartz (dielectric constant: about 3.5). The dielectric 7 is made from 2 mm thick alumina ceramic (dielectric constant: 10). At this time, an electric field strength E (V/m) of the gas flow path 17 is standardized by the electric field strength E0 (V/m) with no dielectric 7, which is shown in FIG. 5B. The electric field strength E of the gas flow path 17 is set to the value of the center in which the electric field strength is the strongest in the gas flow path. The gas flow path 17 is calculated by the parameters, the height H of 2 mm and the distance W between the dielectrics 7, and by taking into account the system of the inductive coupling method. As a result of the calculation, it can be seen that the electric field strength of the gas flow path 17 decreases as the standardized distance of the gas flow path 17, W/H, becomes smaller. In other words, the electric field in the gas flow path 17 varies depending on the distance W between the dielectrics 7. So the smaller the distance W the lower the electric field strength. As a target for effectively reducing the electric field, in this system, the distance W is set to W/H=2.5 or less to effectively reduce the electric field strength to one half.

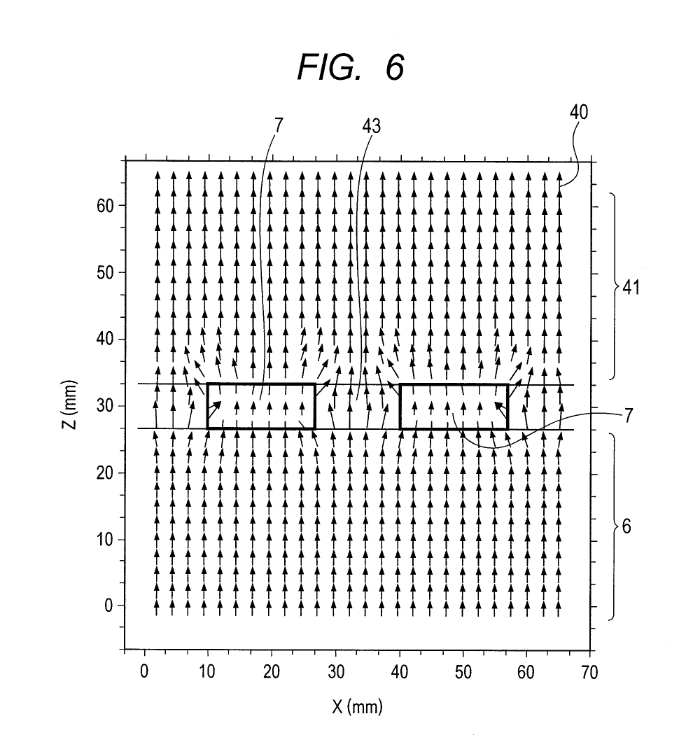

Next, a description will be given of the reason why the electric field of the gas flow path 17 decreases with reference to FIG. 6. FIG. 6 shows the electric field vector in the system shown in FIG. 5A. Reference numeral 40 denotes an electric field vector when the high dielectrics 7 of alumina (dielectric constant: about 10) are inserted into a gap of 4 mm between a quartz plate member 41 and the gas guide plate 6. The electric field vector 40 is directed in a substantially vertical direction in the dielectric vacuum window 4 and the gas guide plate 6 that are located above and below the gas flow path 17. In this case, the electric field vector 40 is directed in the Z direction toward the plasma present under the gas guide plate 6. In general, the gap 43 through which the gas flows is a space through which lean gas flows, and the dielectric constant is 1. When the high dielectrics 7 with a high dielectric constant are provided in the gap 43, the electric field vectors 40 are directed toward the dielectrics 7. Thus, it is possible to reduce the electric field strength in the gap 43 through which the gas flows. In other words, in the vicinity of the dielectrics 7, the electric field vectors are directed toward the dielectrics 7 with a relatively high dielectric constant. As a result, the electric field strength within the gas flow path 17 (corresponding to the gap 43) decreases. This is because the electric field vector 40 propagates in the direction of the inside of the dielectric with a high dielectric constant, and preferably the dielectric constant is higher than the dielectric constant of the gas guide plate 6. Because of this, it can be seen that the degree of the reduction in the electric field strength of the gas flow path 17 is dependent on the dielectric constant of the dielectrics 7 and on the distance W between the dielectrics 7 in FIG. 5. It is to be noted that the above effect may not be obtained if the dielectric is made from a material with a dielectric constant lower than the dielectric constant of quartz and the like.

As a result of the processing of a semiconductor substrate by the plasma processing apparatus with inductive coupling shown in FIG. 1, abnormal discharge was suppressed and highly uniform plasma processing was achieved.

As described above, according to this embodiment, the dielectrics with a dielectric constant higher than that of the dielectric vacuum window and the gas guide plate, are arranged along the gas flow path between them. With this configuration, when the electric field strength is strong as in the case of the inductive coupling method, it is possible to introduce the reactive gas from the upper central portion of the process chamber without causing abnormal discharge. Thus, it is possible to provide the plasma processing apparatus enabling uniform plasma processing over the entire surface of the sample. Further, the ratio of the height H and width W of the gas flow path, W/H, is set to 2.5 or less so that the abnormal discharge can be effectively suppressed.

### Second Embodiment

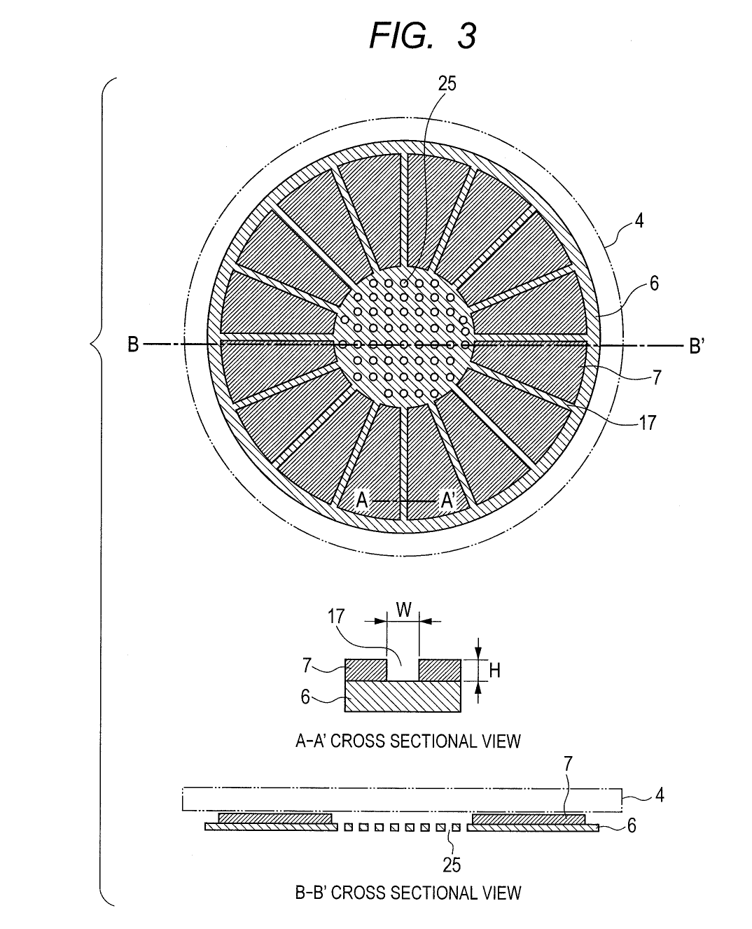

A second embodiment according to the present invention will be described with reference to FIG. 3. It is to be noted that the items described in the first embodiment, but not described in the second embodiment, can also be applied to this embodiment unless special circumstances exist. FIG. 3 is a detailed view of a gas guide plate in the plasma processing apparatus according to this embodiment. The upper diagram is a top view, the middle diagram is an A-A′ cross-sectional view, and the lower diagram is a B-B′ cross-sectional view. In this embodiment, the part including the dielectric vacuum window 4, the gas guide plate 6, and the dielectrics 7 in the first embodiment is replaced by the configuration of the dielectric vacuum window 4, the gas guide plate 6, and the dielectrics 7 shown in FIG. 3. The gas guide plate 6 is made from quartz. Plural gas inlet holes 25 with a diameter of about 0.5 mm are formed in the center of the gas guide plate 6 to introduce gas therefrom. The dielectric 7 is made from alumna ceramic with a thickness H of about 0.5 mm. The dielectrics 7 are bonded to the gas guide plate 6 at a distance W of about 1 mm, so that the gas supplied from the outer periphery of the gas guide plate 6 flows to the center through the gas flow paths 17. According to this embodiment, the process gas can be injected over the planar surface of the sample.

In the plasma processing apparatus of the inductive coupling method shown in FIG. 1, the processing of the semiconductor substrate was processed by the gas guide plate having the dielectrics arranged as shown in FIG. 3. As a result, abnormal discharge was suppressed and highly uniform plasma process was achieved.

As described above, according to this embodiment, it is possible to obtain the same effect as the first embodiment. Further, by providing plural holes in the center of the gas guide plate 6, it is possible to inject the process gas over the planar surface of the sample. As a result, the uniformity can be further improved.

### Third Embodiment

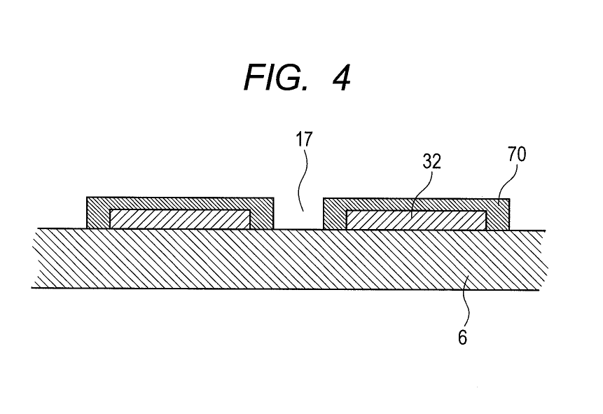

A third embodiment according to the present invention will be described with reference to FIG. 4. It is to be noted that the items described in the first or second embodiment, but not described in the third embodiment, can also be applied to this embodiment unless special circumstances exist. FIG. 4 is a cross-sectional view showing the details of a gas guide plate in the plasma processing apparatus according to the third embodiment. In this embodiment, the high dielectric 7 used in the first and second embodiments is replaced by a conductor 32 covered by a dielectric 70. When using the conductors 32 in place of the high dielectrics 7, it is also effective in directing the electric field vectors to the conductors 32 to reduce the electric field strength of the gas flow path 17, similarly to the case of the dielectrics 7. In other words, the effect of reducing the electric field of the gas flow path 17 can also be obtained by the conductors 32. However, the reactive gas also flows through the gas flow path 17, and there is a risk that the conductor will be eroded if it is made from metal or other materials. For this reason, the protective layer of the dielectric 70 is formed on the surface of the conductor by using the ceramic spraying or resin coating method. It goes without saying that if non-corrosive reactive gas is used for the conductor, there is no need to form the dielectric 70. The dielectric 70 as the protective layer of the conductor is not necessarily a high dielectric.

In the plasma processing apparatus of the inductive coupling method shown in FIG. 1, the semiconductor device was processed by the gas guide plate having the conductors covered with the dielectric 70 shown in FIG. 4. As a result, abnormal discharge was suppressed and highly uniform plasma process was achieved.

As described above, according to this embodiment, the same effect as the first embodiment can be obtained. In addition, the conductor is easy to be processed and effective for cost reduction.

It is to be noted that the present invention is not limited to the foregoing embodiments, and may include various modifications and alternative forms. For example, the forgoing descriptions of the specific embodiments are presented for purposes of illustration and description. They are not intended to be exhaustive or to limit the invention to the precise forms disclosed. Further, a part of the configuration of one embodiment can be replaced by the configurations of the other embodiments, or the configurations of the other embodiments can be added to the configuration of one embodiment. Further, the addition, deletion, and replacement of other configurations can be applied to a part of the configuration of each embodiment.

What is claimed is:

1. A plasma processing apparatus comprising:
a process chamber for plasma processing an object to be processed;
a first dielectric vacuum window for vacuum sealing the top of the process chamber;
an inductive coil provided above the vacuum window;
a radio-frequency power supply for supplying radio-frequency power to the inductive coil;
a gas supply unit for supplying gas into the process chamber; and
a sample holder on which the object to be processed is placed in the process chamber,
wherein the gas supply unit is located near below the vacuum window,
wherein the gas supply unit includes a second dielectric gas guide plate having a gas inlet port in the center thereof, and a third dielectric island member provided in a gap between the vacuum window and the gas guide plate,
wherein the dielectric constant of the third dielectric is higher than the dielectric constant of the first and second dielectrics,
wherein the gas transmitted to a gas flow path formed by the gap and the member, is supplied into the process chamber through the gas inlet port located in the center of the gas guide plate.

2. The plasma processing apparatus according to claim 1,
wherein the member is formed by thermally spraying or depositing insulating material or by attaching insulating sheet.

3. The plasma processing apparatus according to claim 1,
wherein the gas inlet port has a plurality of gas inlet holes.

4. The plasma processing apparatus according to claim 1,
wherein the planar shape of the island member is rectangular or a fan-like shape.

5. The plasma processing apparatus according to claim 1,
wherein when it is assumed that the distance of the member is W and the height of the gas flow path is H, the ratio W/H is 2.5 or less.

6. The plasma processing apparatus according to claim 1,
wherein the inside of the member is formed with a conductor.

7. The plasma processing apparatus according to claim 1,
wherein the island member is provided in the vicinity of the inductive coil.

8. A plasma processing apparatus comprising:
a process chamber for plasma processing an object to be processed;
a first dielectric vacuum window for vacuum sealing the top of the process chamber;
an inductive coil provided above the vacuum window;
a radio-frequency power supply for supplying radio-frequency power to the inductive coil;
a gas supply unit for supplying gas into the process chamber; and
a sample holder on which the object to be processed is placed in the process chamber,
wherein the gas supply unit is located near below the vacuum window,
wherein the gas supply unit includes a second dielectric gas guide plate having a gas inlet port in the center thereof, and a conductor island member provided in a gap between the vacuum window and the gas guide plate,
wherein the gas transmitted to a gas flow path formed by the gap and the member is supplied into the process chamber through the gas inlet port located in the center of the gas guide plate.

9. The plasma processing apparatus according to claim 8,
wherein the conductor is corrosion resistant to the gas.

10. The plasma processing apparatus according to claim 8,
wherein the gas inlet port has a plurality of gas inlet holes.

11. The plasma processing apparatus according to claim 8,
wherein the planar shape of the island member is rectangular or a fan-like shape.

12. The plasma processing apparatus according to claim 8,
wherein the island member is located just below the inductive coil.
